(19) United States
(12) Patent Application Publication
(10) Pub. No.: US 2026/0212064 A1
(43) Pub. Date: Jul. 23, 2026

(54) POWER CONSUMPTION CALCULATION DEVICE

(71) Applicant: FANUC CORPORATION, Yamanashi (JP)

(72) Inventors: Kazumasa YOSHIDA, Yamanashi (JP); Junichi TEZUKA, Yamanashi (JP)

(73) Assignee: FANUC CORPORATION, Yamanashi (JP)

(21) Appl. No.: 19/144,942

(22) PCT Filed: Jan. 13, 2023
(86) PCT No.: PCT/JP2023/000749

§ 371 Date: Jun. 30, 2025

(51) Int. Cl. G06F 30/17

(52) U.S. Cl. CPC G06F 30/17

(57) ABSTRACT

A power consumption calculation device comprises: a machining program acquisition unit that acquires a machining program for a machine tool equipped with a drive device including at least a main spindle or a feed axis; a machine specification acquisition unit that acquires machine specifications of the machine tool; a motor efficiency acquisition unit that acquires motor efficiency of motors in the drive device; a dynamics simulation unit that simulates time-series data of the angular speed of each of the motors and the torque of each of the motors on the basis of the machining program and the machine specifications; and a power consumption calculation unit that calculates, on the basis of the time-series data of the angular speed of each of the motors and the torque of each of the motors and the motor efficiency of each of the motors, time-series data of consumption power consumed by the drive device.

### TECHNICAL FIELD

The present invention relates to a power consumption calculation device.

### BACKGROUND ART

In order to obtain power consumption by a machine tool with high accuracy, it is necessary to measure the power consumption while the machine tool is actually executing a machining program, which takes a long time. A method of estimating a power consumption by a robot system from an operation program by way of simulation is disclosed (for example, see Patent Document 1).

### CITATION LIST

### Patent Document

Patent Document 1: Japanese Unexamined Patent Application, Publication No. 2011-5623

### DISCLOSURE OF THE INVENTION

### Problems to be Solved by the Invention

According to the conventional power simulations, a torque during acceleration is calculated for each motor, and the calculations are performed using gravity and friction as fixed values in many cases, and sufficient accuracy cannot be achieved. For this reason, the conventional power simulations are applicable only to machine tools having a simple axis configuration, and it is necessary to actually measure a power consumption in order to more accurately determine the power consumption. Patent Document 1 does not refer to calculating the torque of each axis using the information regarding all axes in the simulation. Therefore, there is a demand for a power consumption calculation device that highly accurately simulates a power consumption from a machining program without actually operating a machine tool.

### Means for Solving the Problems

One aspect of the present disclosure is directed to a power consumption calculation device including: a machining program acquisition unit configured to acquire a machining program for a machine tool equipped with a drive device including at least a spindle or a feed axis; a machine specification acquisition unit configured to acquire machine specifications of the machine tool; a motor efficiency acquisition unit configured to acquire motor efficiency of one or more motors in the drive device; a dynamics simulation unit configured to simulate time-series data regarding an angular velocity of each of the one or more motors and time-series data regarding a torque of each of the one or more motors based on the machining program and the machine specifications; and a power consumption calculation unit configured to calculate time-series data regarding a power consumption by the drive device based on the time-series data regarding the angular velocity of each of the one or more motors, the time-series data regarding the torque of each of the one or more motors, and the motor efficiency of each of the one or more motors.

### BRIEF DESCRIPTION OF THE DRAWINGS

FIG. 1 is a functional block diagram of a power consumption calculation device according to an embodiment;

FIG. 2 is a functional block diagram related to a function of calculating a power consumption, performed by the power consumption calculation device according to the embodiment;

FIG. 3 is a diagram illustrating an example of a machine tool according to the present embodiment;

FIG. 4 shows graphs illustrating examples of time-series data regarding angles, angular velocities, and angular accelerations of axes;

FIG. 5A is a diagram for explaining a torque during acceleration;

FIG. 5B is a diagram for explaining the torque during acceleration;

FIG. 6A is a diagram for explaining a torque due to gravity;

FIG. 6B is a diagram for explaining the torque due to gravity;

FIG. 7A is a diagram for explaining a torque due to interference force;

FIG. 7B is a diagram for explaining the torque due to interference force;

FIG. 8 is a diagram illustrating an example of machine specifications of a machine tool;

FIG. 9 is a diagram illustrating an example of machine specifications of a machine tool;

FIG. 10 is a diagram illustrating an example of machine specifications of a machine tool; and

FIG. 11 is a diagram illustrating an example of machine specifications of a machine tool.

### PREFERRED MODE FOR CARRYING OUT THE INVENTION

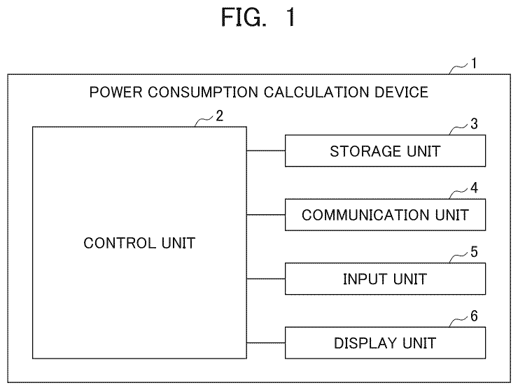

An example of embodiments of the present disclosure will be described below. FIG. 1 is a functional block diagram of a power consumption calculation device 1 according to the present embodiment. The power consumption calculation device 1 simulates a power consumption by a drive device of a machine tool. The power consumption calculation device 1 may be incorporated in a numerical control device that controls the machine tool, or may be configured as a computer device independent of the numerical control device. As illustrated in FIG. 1, the power consumption calculation device 1 includes a control unit 2, a storage unit 3, a communication unit 4, an input unit 5, and a display unit 6.

The control unit 2 is a processor such as a central processing unit (CPU) or the like, and performs various functions by executing programs stored in the storage unit 3.

The storage unit 3 includes storages such as a read only memory (ROM) that stores an operating system (OS), an application program, etc., a random access memory (RAM), a hard disk drive or a solid state drive (SSD) that stores various kinds of other information, and the like.

In the case where the power consumption calculation device 1 is a computer device independent of the numerical control device, the power consumption calculation device 1 includes the communication unit 4 for communicating with the machine tool or the numerical control device via a network in a wired or wireless manner. The communication unit 4 includes a processor, a connector, an electric circuit, and the like for performing the communication. The communication unit 4 acquires data by performing predetermined processing on a communication signal received from the machine tool or the numerical control device, and inputs the acquired data to the control unit 2.

Furthermore, the communication unit 4 generates a communication signal by performing a predetermined processing on data inputted from the control unit 2, and transmits the generated communication signal to the machine tool or the numerical control device. Alternatively, the power consumption calculation device 1 may acquire machine specifications and the like, which will be described later, from an external storage medium or the like, without being connected to the machine tool or the numerical control device via the communication unit 4.

The input unit 5 is an input interface such as a mouse, a keyboard, a touch panel, etc. The display unit 6 is a device that displays an image. The display unit 6 is, for example, a liquid crystal display (LCD), an organic electroluminescence (EL) display, etc.

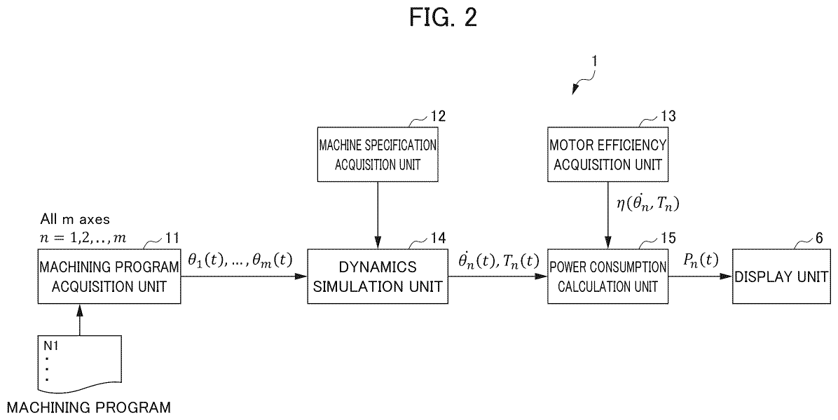

FIG. 2 is a functional block diagram related to a function of calculating a power consumption, performed by the power consumption calculation device 1 according to the present embodiment. As illustrated in FIG. 2, the power consumption calculation device 1 includes a machining program acquisition unit 11, a machine specification acquisition unit 12, a motor efficiency acquisition unit 13, a dynamics simulation unit 14, a power consumption calculation unit 15, and the display unit 6.

The machining program acquisition unit 11 acquires a machining program for a machine tool equipped with a drive device including at least a spindle or a feed axis. For example, in the case where the power consumption calculation device 1 is incorporated in a numerical control device, the machining program acquisition unit 11 acquires a machining program from a storage of the numerical control device. In the case where the power consumption calculation device 1 is a computer device independent of the numerical control device, the machining program acquisition unit 11 may acquire a machining program inputted via the input unit 5 or may acquire a machining program from the machine tool or the numerical control device via the communication unit 4. The machining program acquisition unit 11 may acquire a machining program from an external storage medium or the like.

The machine specification acquisition unit 12 acquires the machine specifications of the machine tool. For example, in the case where the power consumption calculation device 1 is incorporated in the numerical control device, the machine specification acquisition unit 12 acquires the machine specifications from a storage of the numerical control device. In the case where the power consumption calculation device 1 is a computer device independent of the numerical control device, the machine specification acquisition unit 12 may acquire the machine specifications inputted via the input unit 5 or may acquire the machine specifications from the machine tool or the numerical control device via the communication unit 4. The machine specification acquisition unit 12 may acquire the machine specifications of the machine tool from an external storage medium or the like.

The motor efficiency acquisition unit 13 acquires motor efficiency of one or more motors in the drive device of the machine tool. For example, in the case where the power consumption calculation device 1 is incorporated in the numerical control device, the motor efficiency acquisition unit 13 acquires the motor efficiency from a storage of the numerical control device. In the case where the power consumption calculation device 1 is a computer device independent of the numerical control device, the motor efficiency acquisition unit 13 may acquire the motor efficiency inputted via the input unit 5 or may acquire the motor efficiency from the machine tool or the numerical control device via the communication unit 4. The motor efficiency acquisition unit 13 may acquire the motor efficiency from an external storage medium or the like.

The dynamics simulation unit 14 simulates time-series data regarding an angular velocity of each motor and time-series data regarding a torque of each motor, based on the acquired machining program and the acquired machine specifications of the machine tool. Specifically, the dynamics simulation unit 14 acquires angle information regarding all the axes of the machine tool from the machining program, and dynamically simulates the time-series data regarding the angular velocity of each motor and the time-series data regarding the torque of each motor, based on the angle information regarding all the axes and the machine specifications of the machine tool.

The power consumption calculation unit 15 calculates time-series data regarding a power consumption by the drive device of the machine tool, based on the time-series data regarding the angular velocity of each motor, the time-series data regarding the torque of each motor, and the motor efficiency of each motor. The display unit 6 displays the power consumption calculated by the power consumption calculation unit 15.

The torque of each motor includes at least a torque due to gravity and a torque due to interference force. Preferably, the torque of each motor includes the torque due to gravity, the torque due to interference force, a torque during acceleration/deceleration, a torque due to friction, and a torque during cutting.

The machine specifications of the machine tool include at least one of an axis configuration of the machine tool, a friction coefficient of each motor, a moment of inertia of each motor, an eccentric load of each motor, or a workpiece load of each motor.

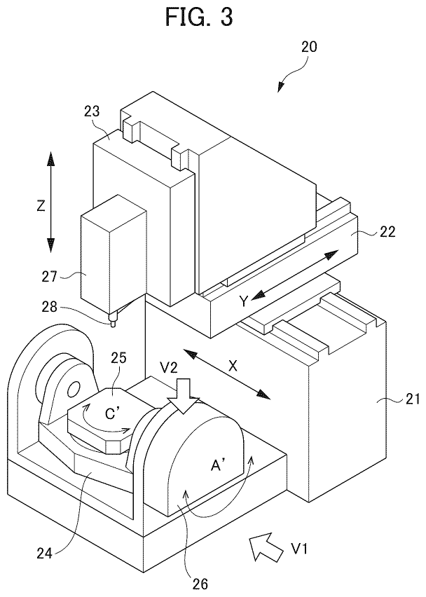

FIG. 3 is a diagram illustrating an example of a machine tool 20 according to the present embodiment. As illustrated in FIG. 3, the machine tool 20 is a table turning type machine having five axes (CA/XYZ). Although the machine tool 20 of the present embodiment is a table turning type machine having five axes (CA/XYZ), which will be described below, the machine tool 20 may be a machine of a different type having a different number of axes.

The machine tool 20 includes a first horizontal linear motion mechanism 21, a second horizontal linear motion mechanism 22, a vertical linear motion mechanism 23, a first rotation mechanism 24, a table 25, a second rotation mechanism 26, a spindle 27, and a tool 28.

The first horizontal linear motion mechanism 21 includes a first base installed on a floor surface, and a first slider supported movably in an X direction (horizontal direction) with respect to the first base. The second horizontal linear motion mechanism 22 includes a second base fixed to the first slider, and a second slider supported movably in a Y direction (horizontal direction) with respect to the second base.

The vertical linear motion mechanism 23 includes a third base fixed to the second slider, and a third slider supported movably in a Z direction (vertical direction) with respect to the third base. The spindle 27 to which the tool 28 can be attached is fixed to the third slider. In the machine tool 20, a workpiece is placed on the table 25, the first rotation mechanism 24 rotates the table 25 around a vertical axis, and the second rotation mechanism 26 tilts the table 25 around a horizontal axis.

The numerical control device generates a speed command based on a machining program, and controls the spindle via a spindle servo control device. Furthermore, the numerical control device generates a position command for a feed axis based on the machining program, and controls the feed axis via a feed axis servo control device.

The spindle 27 includes a spindle motor that is driven in accordance with a drive current from the spindle servo control device. The spindle 27 rotates the tool 28 by being rotated by the spindle motor. Each of the first horizontal linear motion mechanism 21, the second horizontal linear motion mechanism 22, the vertical linear motion mechanism 23, the first rotation mechanism 24, and the second rotation mechanism 26 that serve as the feed axis includes a feed axis motor. The feed axis motors are driven in accordance with a drive current from the feed axis servo control device. The feed axis moves the tool 28 or the workpiece by being rotated by the feed axis motors.

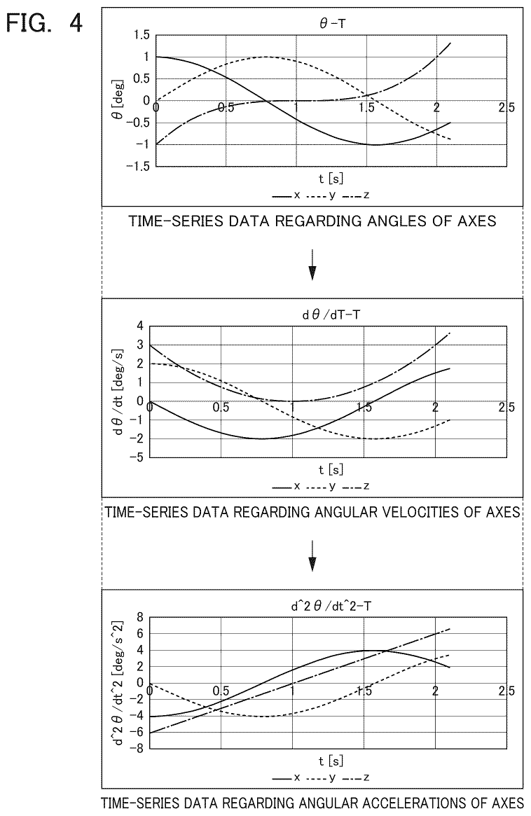

FIG. 4 shows graphs illustrating examples of time-series data regarding angles, time-series data regarding angular velocities, and time-series data regarding angular accelerations of motors that drive the axes. The time-series data illustrated in FIG. 4 includes time-series data regarding angles, time-series data regarding angular velocities, and time-series data regarding angular accelerations of motors that drive the X-axis, the Y-axis, and the Z-axis of the machine tool 20 illustrated in FIG. 3.

For the time-series data regarding angles, the horizontal axis represents the time t [s], and the vertical axis represents the angle θ [deg]. For the time-series data regarding angular velocities, the horizontal axis represents the time t [s], and the vertical axis represents the angular velocity dθ/dt [deg/s]. For the time-series data regarding angular accelerations, the horizontal axis represents the time t [s], and the vertical axis represents the angular acceleration d²θ/dt² [deg/s²].

The torque during acceleration/deceleration, the torque due to friction, the torque due to gravity, the torque due to interference force, and the torque during cutting are expressed by the following generalized functions. A torque of each axis is expressed by a function having the angles θ, the angular velocities dθ/dt, and the angular accelerations d₂θ/dt² of all the axes as inputs. Here, 1, 2, . . . m are numerals corresponding to the respective axes. Each of the following functions does not necessarily use all of the angle θ, the angular velocity dθ/dt, and the angular acceleration d₂θ/dt².
Torque during acceleration/deceleration

$${T}_{a {c}_{n}} ( {θ}_{1} , {θ}_{2} , … , {θ}_{m} , \dot{{θ}_{1}} , \dot{{θ}_{2}} , … , \dot{{θ}_{m}} , \ddot{{θ}_{1}} , \ddot{{θ}_{2}} , … , \ddot{{θ}_{m}} ) \qquad [ Formula 1 ]$$

Torque due to friction

$${T}_{{fr}_{n}} ( {θ}_{1} , {θ}_{2} , … , {θ}_{m} , \dot{{θ}_{1}} , \dot{{θ}_{2}} , … , \dot{{θ}_{m}} , \ddot{{θ}_{1}} , \ddot{{θ}_{2}} , … , \ddot{{θ}_{m}} ) \qquad [ Formula 2 ]$$

Torque due to gravity

$${T}_{{g}_{n}} ( {θ}_{1} , {θ}_{2} , … , {θ}_{m} , \dot{{θ}_{1}} , \dot{{θ}_{2}} , … , \dot{{θ}_{m}} , \ddot{{θ}_{1}} , \ddot{{θ}_{2}} , … , \ddot{{θ}_{m}} ) \qquad [ Formula 3 ]$$

Torque due to interference force

$${T}_{{int}_{n}} ( {θ}_{1} , {θ}_{2} , … , {θ}_{m} , \dot{{θ}_{1}} , \dot{{θ}_{2}} , … , \dot{{θ}_{m}} , \ddot{{θ}_{1}} , \ddot{{θ}_{2}} , … , \ddot{{θ}_{m}} ) \qquad [ Formula 4 ]$$

Torque during cutting

$${T}_{{cut}_{n}} ( {θ}_{1} , {θ}_{2} , … , {θ}_{m} , \dot{{θ}_{1}} , \dot{{θ}_{2}} , … , \dot{{θ}_{m}} , \ddot{{θ}_{1}} , \ddot{{θ}_{2}} , … , \ddot{{θ}_{m}} ) \qquad [ Formula 5 ]$$

Total of torques

$${T}_{n} = {T}_{a {c}_{n}} + {T}_{{fr}_{n}} + {T}_{{g}_{n}} + {T}_{i n {t}_{n}} + {T}_{c u {t}_{n}} \qquad [ Formula 6 ]$$

A power consumption Pn by each motor is given by the following formula.

$${P}_{n} = \int \frac{1}{η} \cdot {T}_{n} \cdot {\dot{θ}}_{n} dt \qquad [ Formula 7 ]$$

while
the motor torque Tₙ(t),
the motor angular velocity \dot{θ}ₙ(t), and
the motor efficiency η
are used.
   The angular velocity of the motor can be calculated from time-series data regarding a motor angle obtained from the machining program, and the motor efficiency can be obtained in advance as a value having the torque and the angular velocity of the motor as variables.

### [Torque During Acceleration]

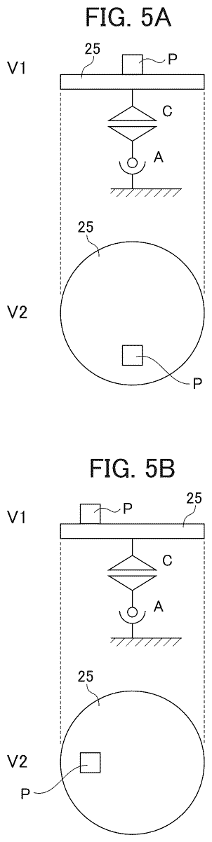

FIGS. 5A and 5B are diagrams for explaining a torque during acceleration. Here, FIGS. 5A, 5B, 6A, 6B, 7A, and 7B each show a viewpoint V1 and a viewpoint V2, which correspond to a viewpoint V1 and a viewpoint V2 shown in FIG. 3. It is assumed that, on the table 25 of the machine tool 20 illustrated in FIGS. 5A and 5B, there is an eccentric load (mass point) P having a mass m, located at a distance r from an axis C, and having the center of gravity at the same height as an axis A.

When the first rotation mechanism 24 (axis C) rotates by θ_{C} from a reference state in which the eccentric load P is present on the central axis of the axis A, the torque required for accelerating and decelerating the axis A is expressed as follows using a moment of inertia JA obtained in advance.

$${T}_{{ac}_{A}} ( {θ}_{C} , \ddot{{θ}_{A}} ) = ( {J}_{A} + {mr}^{2} {sin}^{2} {θ}_{C} ) \cdot \ddot{{θ}_{A}} \qquad [ Formula 8 ]$$

### [Torque Due to Friction]

In the machine tool 20 illustrated in FIG. 3, a torque due to friction produced when the X-axis is driven is expressed as follows using a friction coefficient μ_{X} obtained in advance.

$${T}_{{fr}_{X}} ( \dot{{θ}_{X}} ) = {μ}_{X} \cdot \dot{{θ}_{X}} \qquad [ Formula 9 ]$$

### [Torque Due to Gravity]

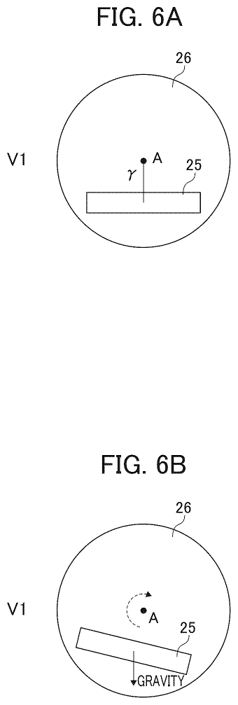

FIGS. 6A and 6B are diagrams for explaining a torque due to gravity. In the machine tool 20 illustrated in FIGS. 6A and 6B, when the second rotation mechanism 26 (axis A) rotates by OA with respect to a reference state in which the table 25 is horizontal, a torque for supporting the axis A against gravity is expressed as follows using a mass M of the table 25 obtained in advance and a distance r between the center of gravity of the table 25 and the rotation center of the axis A.

$${T}_{{g}_{A}} ( {θ}_{A} ) = Mgr sin {θ}_{A} \qquad [ Formula 10 ]$$

### [Torque Due to Interference Force]

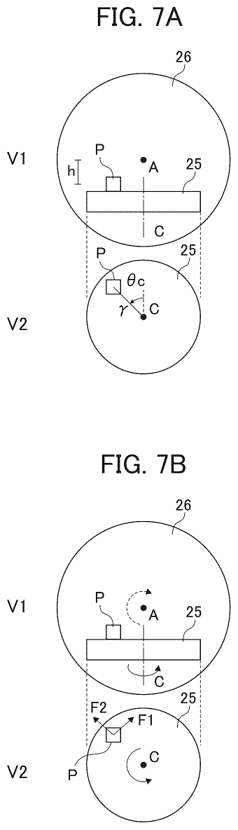

FIGS. 7A and 7B are diagrams for explaining a torque due to interference force. It is assumed that, on the table 25 of the machine tool 20 illustrated in FIGS. 7A and 7B, there is an eccentric load (mass point) P having a mass m and located at a distance r from the axis C. There is assumed to be a distance h between the eccentric load (mass point) P and a plane parallel to the table 25 containing the axis A. With respect to a reference state in which the eccentric load P is on a plane perpendicular to the table 25 containing the axis A and is positioned on a farther side of the table 25 when viewed from the viewpoint V1, the first rotation mechanism 24 (axis C) rotates by θ_{C} to be positioned at a rotated location. When the axis C in this state is accelerated, a centrifugal force F2 and an inertial force F1 have an influence on the rotation axis A. A torque to counteract these forces is represented as follows.

$${T}_{i n {t}_{A}} \qquad [ Formula 11 ]$$

Accordingly, a torque due to interference force is expressed as follows.

$${T}_{i n {t}_{A}} ( {θ}_{C} , \dot{{θ}_{C}} , \ddot{{θ}_{C}} ) \qquad [ Formula 12 ]$$

$$= mr \dot{{θ}_{C}^{2}} sin {θ}_{C} \cdot h - mr \ddot{{θ}_{C}} cos {θ}_{C} \cdot h$$

$$= mrh ( \dot{{θ}_{C}^{2}} sin {θ}_{C} - \ddot{{θ}_{C}} cos {θ}_{C} )$$

### [Torque During Cutting]

Since a torque applied during cutting depends on a tool, the material of an object to be machined, and a relative speed during machining, the torque is given by an optional function in advance.

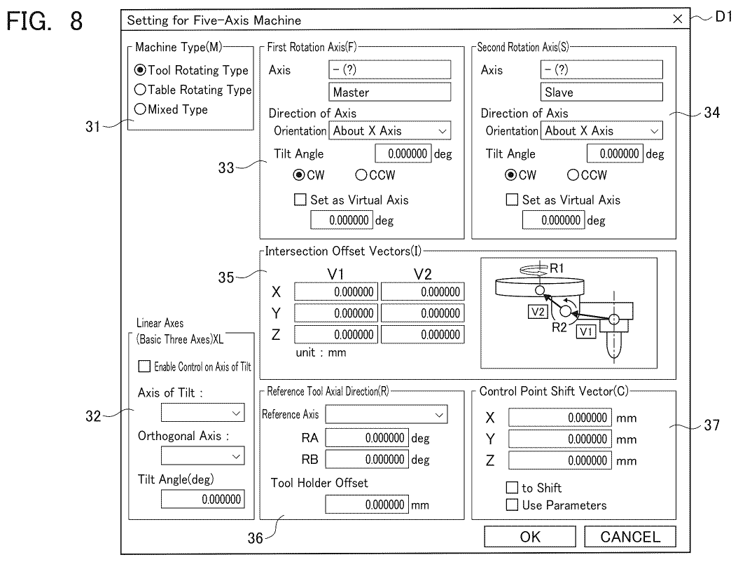

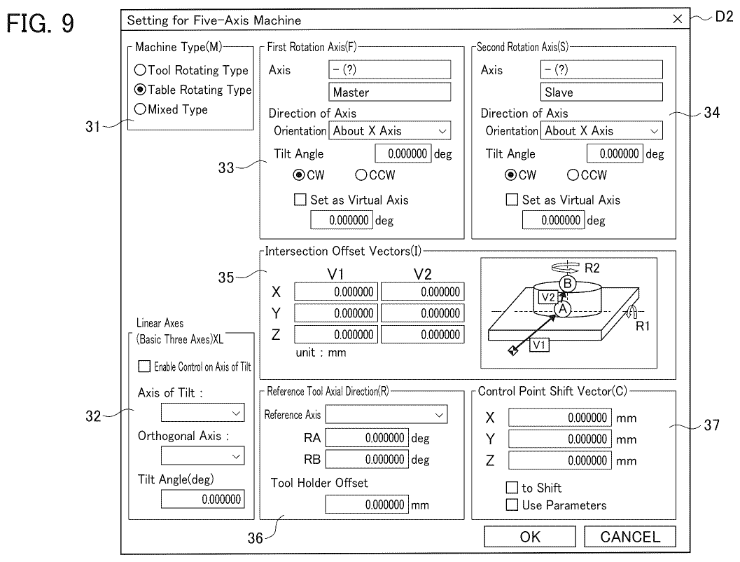

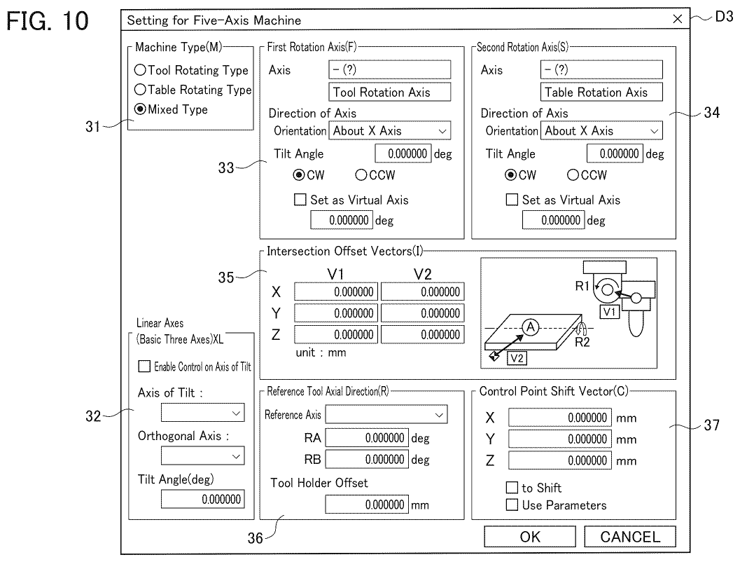

FIGS. 8 to 11 are diagrams illustrating examples of machine specifications of the machine tool 20. Screens D1 to D4 illustrated in FIGS. 8 to 11 are examples of input screens via which the machine specifications of the machine tool 20 are inputted.

As illustrated in FIGS. 8 to 10, the screens D1 to D3 each display boxes for allowing input of items as the machine specifications of the machine tool 20, namely, a box 31 for inputting a machine type, a box 32 for inputting linear axes (basic axes), a box 33 for inputting a first rotation axis, a box 34 for inputting a second rotation axis, a box 35 for inputting intersection offset vectors, a box 36 for inputting a reference tool axial direction, and a box 37 for inputting a control point shift vector.

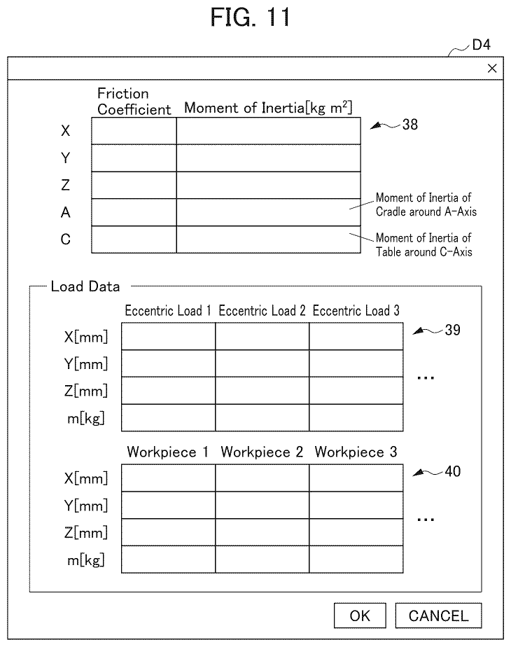

As illustrated in FIG. 11, the screen D4 displays boxes for allowing input of items as the machine specifications of the machine tool 20, namely, a box 38 for inputting friction coefficients of the axes and moment of inertia of the axes, a box 39 for inputting three-dimensional coordinates indicating the position of the center of gravity of eccentric loads and weights of the eccentric loads, and a box 40 for inputting three-dimensional coordinates indicating the position of the center of gravity of workpieces and weights of the workpieces.

As described above, according to the present embodiment, the power consumption calculation device 1 includes: the machining program acquisition unit 11 that acquires a machining program for a machine tool equipped with a drive device including at least a spindle or a feed axis; the machine specification acquisition unit 12 that acquires machine specifications of the machine tool; the motor efficiency acquisition unit 13 that acquires motor efficiency of one or more motors in the drive device of the machine tool; the dynamics simulation unit 14 that simulates time-series data regarding an angular velocity of each motor and time-series data regarding a torque of each motor based on the machining program and the machine specifications of the machine tool; and the power consumption calculation unit 15 that calculates time-series data regarding a power consumption by the drive device of the machine tool based on the time-series data regarding the angular velocity of each motor, the time-series data regarding the torque of each motor, and the motor efficiency of each motor.

Due to this configuration, the power consumption calculation device 1 can calculate the gravity that changes in accordance with a posture of the machine tool and an inertial force that is generated between the axes, based on the axis configuration of the machine tool, information regarding an eccentric load of the rotation axis, and the like, whereby the power consumption calculation device 1 can perform highly accurate simulation even with respect to a machine tool having a complicated axis configuration. Therefore, the power consumption calculation device 1 is capable of highly accurately simulating a power consumption from a machining program without actually operating a machine tool, and contributes to designing of a machine tool that consumes a reduced amount of power.

The power consumption calculation device 1 further includes the display unit 6 that displays the power consumption calculated by the power consumption calculation unit 15. Due to this configuration, the power consumption calculation device 1 can present the calculated power consumption to the user.

The torque of each motor includes at least a torque due to gravity and a torque due to interference force. Preferably, the torque of each motor includes the torque due to gravity, the torque due to interference force, a torque during acceleration/deceleration, a torque due to friction, and a torque during cutting. Since the torque due to gravity and the torque due to interference force change depending on a posture of the machine tool, the power consumption calculation device 1 can highly accurately simulate the power consumption by the machine tool by calculating the torque of each axis in consideration of the posture of the machine tool including all the axes.

The machine specifications of the machine tool includes at least one of an axis configuration of the machine tool, a friction coefficient of each motor, a moment of inertia of each motor, an eccentric load of each motor, or a workpiece load of each motor. Due to this configuration, the power consumption calculation device 1 can calculate the gravity that changes in accordance with a posture of the machine tool and an inertial force that is generated between the axes, based on the axis configuration of the machine tool, information regarding an eccentric load of the rotation axis, and the like, whereby the power consumption calculation device 1 can perform highly accurate simulation even with respect to a machine tool having a complicated axis configuration.

While an embodiment of the present invention has been described in the foregoing, the power consumption calculation device 1 can be implemented by hardware, software, or a combination thereof. The control method performed by the power consumption calculation device 1 can also be implemented by hardware, software, or a combination thereof. Here, the implementation by software means that a computer reads and executes a program for the implementation.

The program can be stored in various types of non-transitory computer readable media and can be provided to a computer. The non-transitory computer readable media include various types of tangible storage media. Examples of the non-transitory computer readable media include a magnetic recording medium (e.g., a hard disk drive), a magnetic-optical recording medium (e.g., a magnetic optical disk), a read only memory (CD-ROM), a CD-R, a CD-R/W, and a semiconductor memory (e.g., a mask ROM, a programmable ROM (PROM), an erasable PROM (EPROM), a flash ROM, and a random access memory (RAM)).

It should be noted that the present disclosure is not limited to the individual embodiments described above in detail. Various additions, substitutions, modifications, partial deletions, and the like can be made to the above embodiments without departing from the spirit of the present disclosure or the spirit of the present disclosure derived from the claims and the equivalents thereof. The above embodiments can also be implemented in combination. For example, in the above-described embodiments, the order of operations and the order of the processes are described as a non-limiting example. The same applies to the case where numerical values or numerical expressions are used in the description of the above embodiments.

The following further discloses additional remarks regarding the foregoing embodiments and modifications thereof.

### Additional Remark 1

A power consumption calculation device (1) including:
a machining program acquisition unit (11) configured to acquire a machining program for a machine tool equipped with a drive device including at least a spindle or a feed axis;
a machine specification acquisition unit (12) configured to acquire machine specifications of the machine tool;
a motor efficiency acquisition unit (13) configured to acquire motor efficiency of one or more motors in the drive device;
a dynamics simulation unit (14) configured to simulate time-series data regarding an angular velocity of each of the one or more motors and time-series data regarding a torque of each of the one or more motors based on the machining program and the machine specifications; and
a power consumption calculation unit (15) configured to calculate time-series data regarding a power consumption by the drive device based on the time-series data regarding the angular velocity of each of the one or more motors, the time-series data regarding the torque of each of the one or more motors, and the motor efficiency of each of the one or more motors.

### Additional Remark 2

The power consumption calculation device according to Additional Remark 1, further including a power consumption display unit (6) configured to display the power consumption calculated.

### Additional Remark 3

The power consumption calculation device according to Additional Remark 1 or 2, in which the torque of each of the one or more motors includes at least a torque due to gravity and a torque due to interference force.

### Additional Remark 4

The power consumption calculation device according to Additional Remark 3, in which the torque of each of the one or more motors includes the torque due to gravity, the torque due to interference force, a torque during acceleration/deceleration, a torque due to friction, and a torque during cutting.

### Additional Remark 5

The power consumption calculation device according to Additional Remark 1 or 2, in which the machine specifications of the machine tool include at least one of an axis configuration of the machine tool, a friction coefficient of each of the one or more motors, a moment of inertia of each of the one or more motors, an eccentric load of each of the one or more motors, or a workpiece load of each of the one or more motors.

### EXPLANATION OF REFERENCE NUMERALS

1: Power consumption calculation device
2: Control unit
3: Storage unit
4: Communication unit
5: Input unit
6: Display unit
11: Machining program acquisition unit
12: Machine specification acquisition unit
13: Motor efficiency acquisition unit
14: Dynamics simulation unit
15: Power consumption calculation unit

1. A power consumption calculation device comprising:
a machining program acquisition unit configured to acquire a machining program for a machine tool equipped with a drive device including at least a spindle or a feed axis;
a machine specification acquisition unit configured to acquire machine specifications of the machine tool;
a motor efficiency acquisition unit configured to acquire motor efficiency of one or more motors in the drive device;
a dynamics simulation unit configured to simulate time-series data regarding an angular velocity of each of the one or more motors and time-series data regarding a torque of each of the one or more motors based on the machining program and the machine specifications; and
a power consumption calculation unit configured to calculate time-series data regarding a power consumption by the drive device based on the time-series data regarding the angular velocity of each of the one or more motors, the time-series data regarding the torque of each of the one or more motors, and the motor efficiency of each of the one or more motors.

2. The power consumption calculation device according to claim 1, further comprising:
a power consumption display unit configured to display the power consumption calculated.

3. The power consumption calculation device according to claim 1, wherein the torque of each of the one or more motors includes at least a torque due to gravity and a torque due to interference force.

4. The power consumption calculation device according to claim 3, wherein the torque of each of the one or more motors includes the torque due to gravity, the torque due to interference force, a torque during acceleration/deceleration, a torque due to friction, and a torque during cutting.

5. The power consumption calculation device according to claim 1, wherein the machine specifications of the machine tool include at least one of an axis configuration of the machine tool, a friction coefficient of each of the one or more motors, a moment of inertia of each of the one or more motors, an eccentric load of each of the one or more motors, or a workpiece load of each of the one or more motors.
